(19) United States
(12) Patent Application Publication
(10) Pub. No.: US 2013/0151184 A1
(43) Pub. Date: Jun. 13, 2013

(54) Meter Device

(71) Applicants: Sergio Rossi, Genoa (IT); Renato Bessegato, Montebelluna (TV) (IT)

(72) Inventors: Sergio Rossi, Genoa (IT); Renato Bessegato, Montebelluna (TV) (IT)

(73) Assignee: Infineon Technologies Austria AG, Villach (AT)

(21) Appl. No.: 13/313,460

(22) Filed: Dec. 7, 2011

(51) Int. Cl. G06F 19/00; G01R 19/00

(52) U.S. Cl. 702/64

(57) ABSTRACT

A meter arrangement includes a measuring unit. The measuring unit is configured to be coupled to a phase of a power line, to measure at least one parameter of the phase and to provide data representing the measured parameter. A control unit is coupled to the measuring unit and is configured to process the data provided by the measuring unit. A data communication channel is configured to couple the measuring unit and the control unit and provides a path for data transmission between the units. The data communication channel includes a magnetic transfer device. A power channel is configured to couple the measuring unit and the control unit. A path for energy transmission is provided between the measuring and control units. The power channel includes a magnetic transfer device.

### TECHNICAL FIELD

Embodiments of the present invention relate to a meter arrangement, in particular an arrangement for measuring and processing parameters of a power line.

### BACKGROUND

Power line meter devices can be used, for example, to track one or more parameters on one or multiple phases of a power line or a power grid. A meter device is usually an electronic device which is coupled to the power line and which is adapted to measure the voltage and current of the power line. Data representing the voltage and current of the power line can be processed, in order to determine power consumption, for example. This data can be stored. The user and the utility provider, for example, are then able to access this data at any time. Power grid metering, for example, can help utility providers manage overall energy consumption patterns and cope with peak-demand challenges. Power line metering can help customers to better manage their own usage, for example.

Several solutions for electric meters on single- or poly-phase power lines or power grids already exist. In a typical polyphase meter arrangement, for example, the power parameters of each phase can be measured using a current transformer and a voltage transformer. For single-phase meter arrangements, solutions are known which use resistors, shunts, voltage dividers and/or current transformers. The power-factor parameters, or other parameters of the power line, can be calculated from the sampled data using, for example, a digital signal processor.

Because each phase has a different reference voltage, one metering unit is needed to measure the current of each phase. Each of the units is powered separately. For galvanically insulating one phase and the corresponding metering unit, current transformers, hall sensors or optocouplers can be used. For all solutions many different components are needed for galvanic insulation and power supply. Therefore, these solutions require much space and have high bill-of-materials costs. When using magnetic sensors, for example, there is also a risk of tampering with such metering devices.

Because the number of components and cost are always crucial, there is a need for a meter arrangement which requires fewer components and therefore is more optimized in terms of cost and space as compared to current solutions.

### SUMMARY OF THE INVENTION

A meter arrangement is disclosed. In accordance with one embodiment of the present invention the meter arrangement includes a measuring unit. The measuring unit is configured to be coupled to a phase of a power grid, to measure at least one parameter of the energy phase and to provide data representing the measured parameter. A control unit is coupled to the first component and is configured to process the data provided by the measuring unit. A data communication channel is configured to couple the measuring unit and the control unit and provides a path for data transmission between the units. The data communication channel comprises a magnetic transfer device. A power channel is configured to couple the measuring unit and the control unit and provides a path for energy transmission between the units. The power channel comprises a magnetic transfer device.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates in a block diagram the basic principle of the embodiment of the present invention;

FIG. 2 illustrates in a block diagram one example for the implementation of the transmission of data and energy in the present invention;

FIG. 3 illustrates in a block diagram one example for the implementation of clock transmission in the present invention;

FIG. 4 illustrates in a block diagram one example for the implementation of the embodiment of the present invention; and

FIG. 5 illustrates in a block diagram one example of an arrangement for the use in a polyphase power grid.

### DETAILED DESCRIPTION OF ILLUSTRATIVE EMBODIMENTS

In the following detailed description, reference is made to the accompanying drawings, which form a part thereof, and in which is shown by way of illustration specific embodiments in which the invention may be practiced. In this regard, directional terminology, such as “top”, “bottom”, “front”, “back”, “leading”, “trailing” etc., is used with reference to the orientation of the figures being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

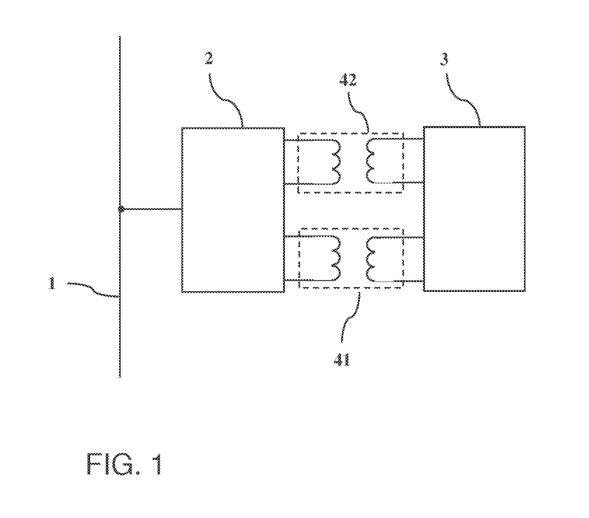

FIG. 1 shows a meter arrangement according to one embodiment of the present invention. The meter arrangement includes a measuring unit 2 that is coupled to the phase 1 of a power grid. The meter arrangement, however, does not necessarily have to be coupled to a power grid. It could be coupled to any power line. The measuring unit 2 is configured to measure at least one parameter of the phase 1, such as, for example, a voltage between the phase and a reference potential, such as ground, or a current. A control unit 3 is coupled to the measuring unit 2 via a data communication channel 41, and the measuring unit 2 is coupled to the control unit 3 via a power channel 42. The data communication channel 41 provides a path for data transmission between the measuring unit 2 and the control unit 3. Via this data communication channel 41 data can be sent from the measuring unit 2 to the control unit 3 or from the control unit 3 to the measuring unit 2. Data that are sent via the communication channel from the measuring unit 2 to the control unit 3 are, for example, data representing the parameters measured by the measuring unit 2.

The power channel 42 provides a path for energy transmission between the measuring unit 2 and the control unit 3. Via the power channel 42 the control unit 3 provides to the measuring unit 2 the energy necessary to operate. Thus, no additional power supply of the measuring unit 2 is required.

Both, the data communication channel 41 and the power channel 42 comprise a magnetic transfer device, which could be a transformer or a coreless transformer, for example, with a primary winding connected to one of the measuring unit 2 and the control unit 3, and with a secondary winding connected to the other one of the measuring unit 2 and the control unit 3. Transformers and other magnetic transfer devices generally can be used to transfer data and/or energy from one circuit to another keeping the circuits galvanically insulated from each other.

The magnetic transfer device in the power channel 42 is primarily used to transmit energy from the control unit 3 to the measuring unit 2. However, it is also possible that energy is transmitted in the other direction. The magnetic transfer device in the data communication channel 41 is used to transfer data from the measuring unit 2 to the control unit 3, or vice versa. The measuring unit 2, which measures the parameters of the phase 1, provides data representing the measured parameter to the control unit 3, for example. The control unit 3 is configured to further process this data to determine power consumption, for example. If necessary, it is also possible to send data from the control unit 3 to the measuring unit 2 via the data communication channel 41.

In conventional meter arrangements, the measuring unit 2 and the control unit 3 each have a dedicated power supply. This increases the number of parts which are needed, as well as the space and total cost. In the meter device according to FIG. 1, however, the energy required to power the measuring unit 2 is transmitted from the control unit 3, via a dedicated transmission path. Thus, fewer components than in conventional arrangements are needed, which reduces size and cost.

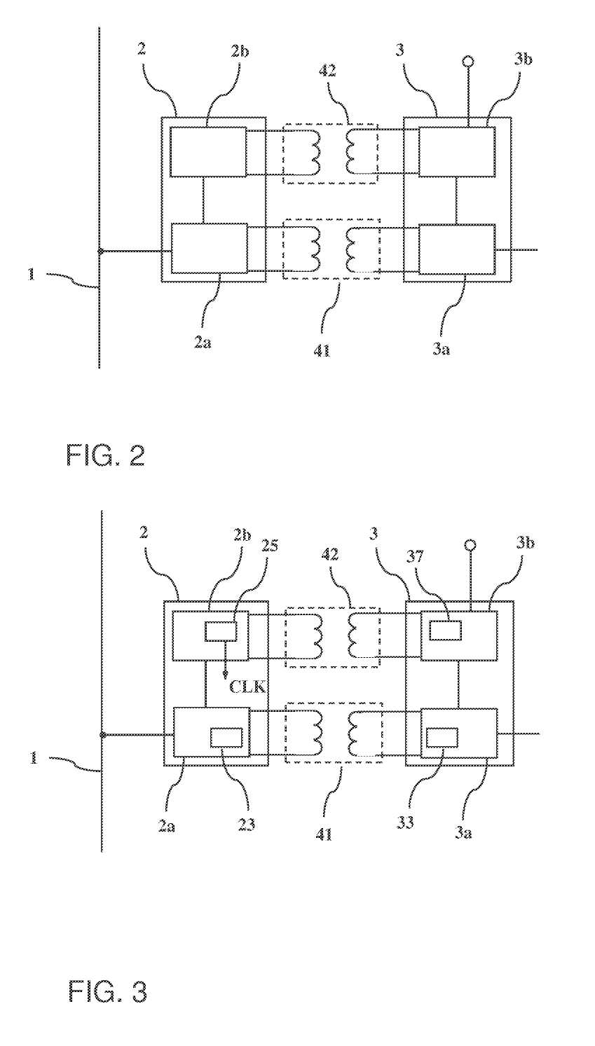

FIG. 2 shows an embodiment of a meter arrangement in greater detail. Referring to FIG. 2, the measuring unit 2 includes a measurement and transmission unit 2a and a power supply unit 2b, and the control unit 3 includes a data receiving and processing unit 3a and a power supply unit 3b. Each unit is coupled to one of the magnetic transfer devices of the data communication channel 41 and the power channel 42.

The power supply unit 2b receives energy via the magnetic transfer device and is configured to power the measurement and transmission section 2a. A magnetic transfer device, such as the device in the power channel 42, generally cannot provide a constant power transmission, but transmits an oscillating or pulsed signal. The power supply unit 2b is configured to generate a DC supply voltage from the oscillating or pulsed signal received from the control unit 3 via the power channel 42.

The power the supply unit 2b receives via the power channel 42 is provided by the power supply unit 3b of the control unit 3. The power supply unit 3b is, for example, coupled to a dedicated power supply (not illustrated). This dedicated power supply also supplies the data receiving and processing section 3a of the control unit 3.

The measurement and transmission unit 2a of the measuring unit 2 is coupled to the phase 1 of the power grid and is configured to measure at least one parameter of the phase 1, such as a voltage between the phase and a reference potential, or a current, and to provide data representing the at least one parameter via the data communication channel 41. According to one embodiment, the voltage and the current are measured, so as to be able to calculate a power consumption of a load (not illustrated) connected to the phase. The data receiving and processing unit 3a of the control unit 3 receives this data from the measurement and transmission unit 2a of the measuring unit 2 and is configured to process this data. When data representing a voltage and a current are transmitted from the measuring unit 2 to the control unit 3, the control unit 3 can be configured to determine a power consumption of a load connected to the phase. The control unit 3 can be configured to provide processed data, such as the power consumption or the digitized current and/or voltage, for example, to other components (not shown), which might further be coupled to the control unit 3. For example, processed data could be provided to a microcontroller unit or any other device, which can further evaluate this data.

Reference is now made to FIG. 3. According to one embodiment, the power channel 42 is not only used to transfer energy, but is also used to transfer a clock signal from the control unit 3 to the measuring unit 2. In some cases it might be necessary to synchronize the clocks of the measuring unit 2 and the control unit 3. Especially in digital circuits, a clock signal might be needed, to coordinate the actions of the circuit. A clock signal is generated by a clock generator. The control unit 3 might include a clock generator, or clock recovery unit 37 within its power supply unit 3b in order to generate a clock signal. This clock signal can be transferred via the magnetic transfer device of the power channel 42 or the magnetic transfer device of the data communication channel 41 to the measuring unit 2. The measuring unit 2 might also include a clock recovery unit 25 within its power supply unit 2b. The clock recovery unit 25 of the measuring unit 2 is configured to receive clock signals from the clock generation unit 37 of the control unit 3 and generate a clock signal CLK, which can be used to adapt the clock of the measuring unit 2 to the clock of the control unit 3.

This is shown in FIG. 3. In the shown example, the measuring unit 2 and the control unit 3 each include a send receive module 23, 33 within their transmission units 2a and 3a. These modules 23, 33 can be used to send or receive data via the data communication channel 41. The clock recovery unit 37 can generate a reference clock signal or master clock signal which represents the clock of the send receive module 33 of the control unit 3 and transfer this master clock signal via the power channel 42. The clock recovery unit 25 in the measuring unit 2, can receive this master clock signal, generate a CLK signal which is synchronized to the clock signal received from the control unit and provide it to the send receive module 23 in the measuring unit 2. In this way, the clocks of the measuring unit 2 and the control unit 3 can be synchronized. Another alternative of synchronizing the clocks of the measuring unit 2 and the control unit 3 would be to generate a clock signal CLK, which represents the clock of the send receive module 23 of the measuring unit 2, using the clock recovery unit 25. Via the data communication channel, for example, this clock signal CLK can be transferred to the control unit 3 where the clock recovery unit 37 can generate a clock signal which is synchronized to the clock signal of the measuring unit.

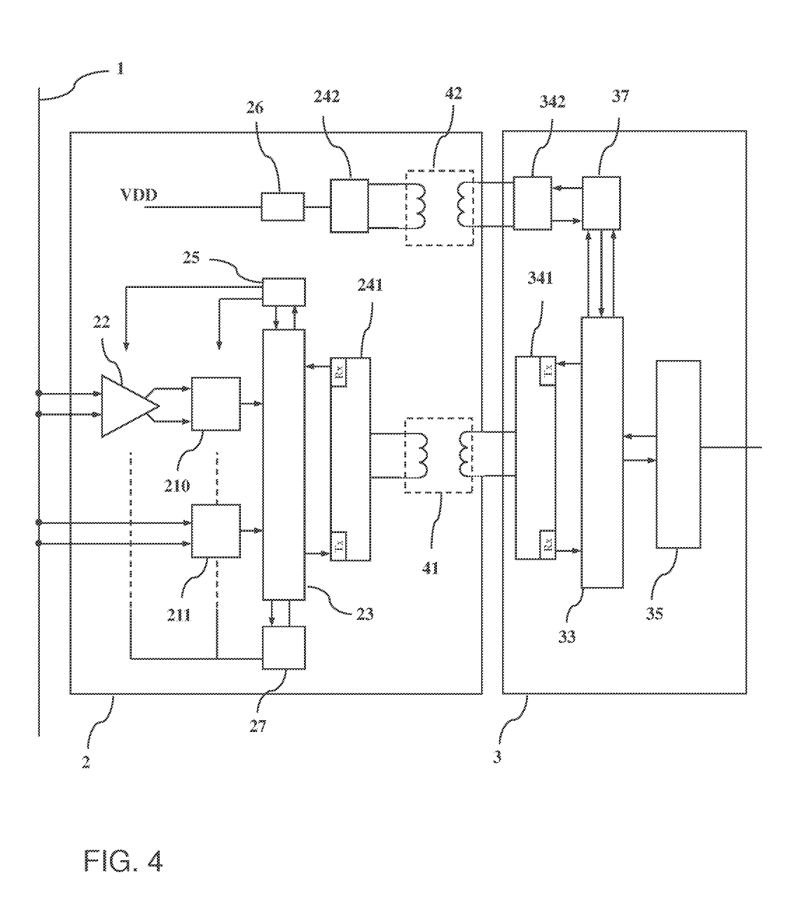

FIG. 4 shows an even more detailed example of a meter arrangement according to the current invention. The measuring unit 2 includes a first analog to digital converter 210 to measure, for example, a current of the phase 1. Any other parameters of the phase 1, like a voltage for example, might be measured instead or additionally to the current. The analog to digital converter 210 converts the analog signal representing the measured current into a digital signal. Instead of measuring more than one parameter of the phase 1 with only one analog to digital converter 210, a second analog to digital converter 211 can be used to measure a different parameter of the phase 1 than the analog to digital converter 210. For example, the analog to digital converter 210 might measure the current and the analog to digital converter 211 might measure the voltage of the phase 1. The analog to digital converter 211 is directly connected to phase 1 in this example. It is also possible to couple a programmable gain amplifier 22 between the phase 1 and the analog to digital converter 210. The programmable gain amplifier 22 and the analog to digital converter 210 then form an analog front end which performs the signal conversion. The programmable gain amplifier 22, however, is optional, as it is not always necessary to first amplify the analog signal before it is converted into a digital signal.

The send receive module 23 is the module which generates the clock for the analog to digital converter, synchronizes this clock with a master clock and performs error correction coding for the signal to be sent to the control unit 3. In this example the magnetic transfer device which is used for signal transmission is a coreless transformer. A transmitting part 241 is needed to modulate a signal which is to be transmitted. The transmitting part 241 receives the digitalized signal from the send receive module 23, modulates the signal and transmits it via the data communication channel 41, which consists of the two coils of the coreless transformer.

For transmission, the digital signal is converted into electric pulses. A receiving module 341 of the control unit 3 receives these electric pulses and demodulates them, in order to recover the original signal. This signal is then sent to a send receive module 33, which performs the decoding of the signal. A coreless transformer might also be used for the power channel 42. Energy is mainly transmitted from the control unit 3 to the measuring unit 2, in order to power the components of the measuring unit 2. Therefore, part 342 mainly functions as a transmitting part and part 242 mainly functions as a receiving part. Still, energy could also be transmitted in the other direction, from the measuring unit 2 to the control unit 3. In such cases, part 242 would function as transmitting and part 342 as receiving part. The transmitting part would, in each case, perform the modulation, the receiving part would perform the demodulation. A power supply unit 26 in the measuring unit 2 receives the transmitted energy and provides it to the other components of the measuring unit 2.

As mentioned before, also a clock signal might be sent via the power channel 42 from the control unit 3 to the measuring unit 2. If needed, it would, of course, also be possible to send a clock signal via the data communication channel 41 from the measuring unit 2 to the control unit 3. The clock recovery units 25, 37 are both able to generate a clock signal from the send/receive modules 23, 33 and synchronize this clock with a clock signal received via one of the channels 41, 42.

It is further possible to transmit configuration data from the control unit 3 to the measuring unit 2 or vice versa, if needed. A configuration register 27 in the measuring unit 2 can store configuration data received from the control unit 3.

The control unit 3 might further be connected to other components, in order to transmit the data received from the measuring unit 2. Therefore, a dedicated or standard interface 35 could be used, to send data to and/or to receive data from components connected to the control unit via the interface 35. The interface 35 could be a dedicated, e.g. differential or digital, interface. It could also be a standard interface like an SPI interface, for example.

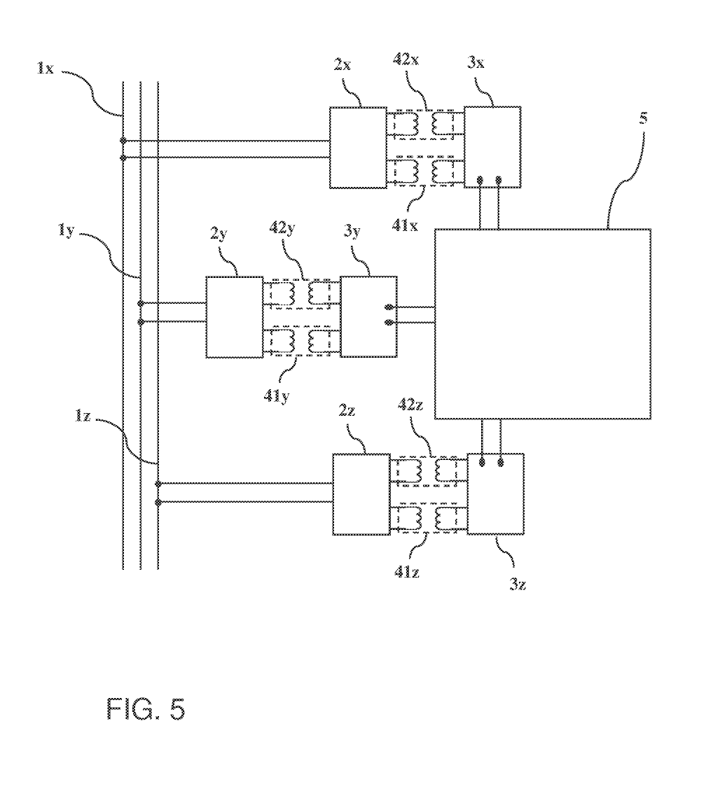

FIG. 5 shows, how the meter arrangement described above could be used on a polyphase power line. In a power grid, for example, there is often more than one phase. Therefore it might be possible to measure parameters of two or three phases, for example. The power grid shown in FIG. 5 has three phases 1x, 1y and 1z. On each of the phases parameters like voltage and current might be measured. However, any other parameter of the power grid or a power line might be measured instead or additionally. A meter arrangement is connected to each phase, as it is generally necessary to galvanically insulate the phases from each other. One meter arrangement, for example, might be connected to phase 1x. The measuring unit 2x is connected to the phase 1x and is further connected to the control unit 3x via the data communication channel 41x and the power channel 42x. The control unit 3x is connected to a microcontroller 5. Instead of a microcontroller 5, any other device could be connected to the control unit 3x, which is able to further evaluate the data processed by the meter arrangement.

A second meter arrangement is connected to the second phase 1y. The meter arrangement consists of a measuring unit 2y, a control unit 3y, a data communication channel 41y and a power channel 42y. The meter arrangement might measure any parameter of phase 1y and provide processed data to the microcontroller 5. A third meter arrangement is connected to the third phase 1z and the microcontroller 5. In this way, only one microcontroller 5 is needed to evaluate the data of all three phases 1x, 1y and 1z. The phases 1x, 1y and 1z on the other hand are galvanically insulated from each other, which might be necessary in various applications.

It is possible to measure parameters of one or two, or of all three phases of a polyphase power line, by using one or more meter arrangements according to the present invention. In case a galvanic insulation of two or more phases is not needed, one meter arrangement could also be used to measure parameters of more than one phase.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A meter arrangement comprising:
a measuring unit, configured to be coupled to a phase of a power line, to measure at least one parameter of the phase and to provide data representing the measured parameter;
a control unit, coupled to the measuring unit and configured to process the data provided by the measuring unit;
a data communication channel, configured to couple the measuring unit and the control unit thereby providing a path for data transmission between the units, the data communication channel comprising a first magnetic transfer device; and
a power channel, configured to couple the measuring unit and the control unit thereby providing a path for energy transmission between the measuring unit and control unit, the power channel comprising a second magnetic transfer device.

2. The meter arrangement according to claim 1, wherein the parameter measured by the measuring unit comprises a voltage of the phase and a current of the phase.

3. The meter arrangement according to claim 1, wherein the first and second magnetic transfer devices comprise transformers.

4. The meter arrangement according to claim 1, wherein the first and second magnetic transfer devices comprise coreless transformers.

5. The meter arrangement according to claim 1, wherein the control unit is further configured to send a clock signal to or receive a clock signal from the measuring unit.

6. The meter arrangement according to claim 5, wherein the clock signal is sent via the power channel.

7. The meter arrangement according to claim 6, wherein the measuring unit is further configured to receive a clock signal from or send a clock signal to the control unit.

8. The meter arrangement according to claim 2, wherein the measuring unit comprises an analog-to-digital converter to measure the voltage or the current of the phase.

9. The meter arrangement according to claim 2, wherein the measuring unit comprises a first analog-to-digital converter to measure the voltage and a second analog-to-digital converter to measure the current of the phase.

10. A method of operating a meter arrangement, the method comprising:
measuring at least one parameter of a phase of a power line with a measuring unit;
determining data representing the measured parameter;
transmitting the data from the measuring unit to a control unit via a data communication channel that comprises a first magnetic transfer device;
processing the data transmitted from the measuring unit at the control unit; and
transferring energy from the measuring unit to the control unit via a power channel that comprises a second magnetic transfer device.

11. The method according to claim 10, wherein the parameter measured by the measuring unit comprises a voltage or a current of the phase.

12. The method according to claim 10, wherein the first and second magnetic transfer devices are transformers.

13. The method according to claim 12, wherein the first and second magnetic transfer devices are coreless transformers.

14. The method according to claim 10, further comprising communicating a clock signal between the control unit and the measuring unit.

15. The method according to claim 14, wherein the clock signal is communicated via the power channel.

16. The method according to claim 15, wherein communicating the clock signal comprises transmitting the clock signal from the control unit to the measuring unit.

17. The method according to claim 15, wherein communicating the clock signal comprises transmitting the clock signal from the measuring unit to the control unit.

18. The method according to claim 10, wherein measuring at least one parameter comprises measuring a voltage or a current of the phase with an analog-to-digital converter.

19. The method according to claim 10, wherein measuring at least one parameter comprises measuring a voltage of the phase with a first analog-to-digital converter and measuring a current of the phase with a second analog-to-digital converter.
